(19) United States
(12) Patent Application Publication
(10) Pub. No.: US 2010/0232614 A1
(43) Pub. Date: Sep. 16, 2010

(54) QUANTUM MECHANICAL TUNNELING AUDIO DISTORTION DEVICE

(76) Inventor: Allen Patrick Myers, Hampstead, MD (US)

Correspondence Address: Allen Myers, 1378 N Main St, Hampstead, MD, 21074, US

(21) Appl. No.: 12/716,297

(22) Filed: Mar. 3, 2010

Related U.S. Application Data
(60) Provisional application No. 61/159,078, filed on Mar. 10, 2009.

(51) Int. Cl. H03G 3/02

(52) U.S. Cl. 381/61

(57) ABSTRACT

The present invention relates to an electronic audio processing device and more particularly an audio distortion device. Audio is distorted using a quantum mechanical tunneling device, such that distortion does not need to occur on the peaks of the audio waveform, but can rather occur on rising or falling edges of the waveform. Further, this technique allows for more unusual distortions, as quantum mechanical tunneling devices can exhibit a region of negative resistance that cannot be achieved with standard diodes.

### CROSS-REFERENCE TO RELATED APPLICATION

This application claims the benefit of U.S. provisional application Ser. No. 61/159,078 filed Mar. 10, 2009.

### BACKGROUND OF THE INVENTION

1. Field of the Invention

The present invention is in the technical field of electronic audio processing devices. More particularly, the present invention is in the technical field of audio distortion devices.

2. Discussion of the Related Art

In the realm of live and recorded musical performances, the sounds of amplified musical instruments are commonly electronically altered to create a variety of sound enhancements and effects. One of the more common types of effect is the intentional introduction of distortion to the audio signals produced by the instrument to create a fuller or grittier sound. Devices that perform this function are commonly referred to as “distortion pedals” or “fuzz boxes”.

Conventional audio distortion devices or “fuzz boxes” achieve distortion by clipping the top and/or bottom of the audio waveform, usually with standard diodes or transistors configured to perform as diodes. This type of clipping distortion has been described in U.S. Pat. No. 4,180,707 by Moog, U.S. Pat. No. 5,032,796 by Tiers and others.

A major limitation of these distortion devices is that the clipping occurs only on the top and/or bottom of the audio waveform. A greater variety of sound effect could be achieved with a device that could also distort the rising and/or falling edges of the audio waveform, thus expanding the tonal limitations of the related art.

Another limitation of these distortion devices involves the diode used to achieve the clipping. An increase in forward voltage of the diode causes an increase in electrical current flow. The result is that the shape of the clipped region of the audio waveform is flat. A more versatile sonic palate could be achieved by clipping with a quantum mechanical tunneling device, such a tunnel diode, which has a region where an increase in forward voltage causes a decrease in electrical current (known as “negative resistance”).

### SUMMARY OF THE INVENTION

The present invention is directed to an audio distortion device that overcomes the limitations of the related art.

The present invention is an audio distortion device that achieves distortion by passing an audio signal through a quantum mechanical tunneling device, such as a tunnel diode.

The advantages of the present invention include, without limitation, that distortion does not need to occur on the peaks of the audio waveform, but can rather occur on rising or falling edges of the waveform. Further, this technique allows for more unusual distortions, as quantum mechanical tunneling devices can exhibit a region of negative resistance that cannot be achieved with standard diodes.

It is to be understood that both the foregoing general description and the following detailed description are exemplary and explanatory and are intended to provide further explanation of the invention as claimed.

### BRIEF DESCRIPTION OF THE DRAWING

FIG. 1 is block diagram view of the present invention.

### DETAILED DESCRIPTION OF THE INVENTION

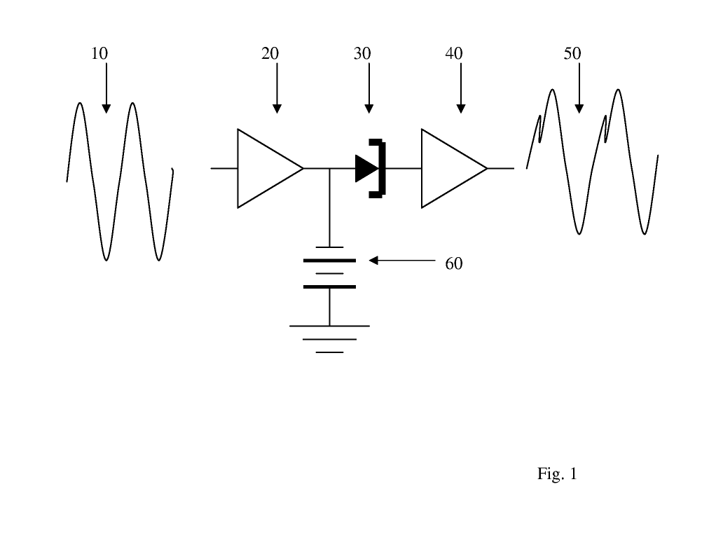

Referring now to the invention in more detail in FIG. 1 there is shown an audio input signal 10 feeding into an optional audio buffer amplifier 20 which interfaces to the quantum tunneling component 30.

The quantum tunneling component 30 is driven to the point where distortion occurs. Optionally the quantum tunneling component 30 can be integrated with the buffer amplifer 20.

The output of the quantum tunneling component 30 is fed into an optional audio output buffer amplifier 40, which results in the distorted audio output signal 50.

The quantum tunneling component may be any such component that exhibits quantum mechanical tunneling properties such as, but not limited to, a tunnel diode.

Referring still to FIG. 1, an optional electrical bias 60 may be applied to the quantum tunneling component to control where the distortion occurs on the audio waveform.

A practical example would be to use a tunnel diode in the feedback loop of an operational amplifier.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A quantum mechanical tunnel audio distortion device for introducing distortion to an audio signal applied to an input terminal thereof, comprising:
an input buffering amplifier in communication with audio signal input;
a distortion component in communication with the input buffering amplifier;
an output buffering amplifier in communication with the distortion component; and
a biasing circuit in communication with the distortion component.

2. The quantum mechanical tunnel audio distortion device of claim 1, wherein the input buffering amplifier matches the audio signal input impedance to the distortion component impedance.

3. The quantum mechanical tunnel audio distortion device of claim 1, wherein the input buffering amplifier drives the distortion component to a distorting region.

4. The quantum mechanical tunnel audio distortion device of claim 1, wherein the input buffering amplifier can accept feedback from the distortion component.

5. The quantum mechanical tunnel audio distortion device of claim 1, wherein the distortion component a quantum mechanical tunneling device.

6. The quantum mechanical tunnel audio distortion device of claim 3, wherein the quantum mechanical tunneling device is a tunnel diode.

7. The quantum mechanical tunnel audio distortion device of claim 3, wherein the quantum mechanical tunneling device is a resonant tunneling diode.

8. The quantum mechanical tunnel audio distortion device of claim 3, wherein the quantum mechanical tunneling device is a quantum tunneling transistor.

9. The quantum mechanical tunnel audio distortion device of claim 3, wherein the quantum mechanical tunneling device is a metal insulator insulator metal diode.

10. The quantum mechanical tunnel audio distortion device of claim 3, wherein the quantum mechanical tunneling device is a quantum dot transistor.

11. The quantum mechanical tunnel audio distortion device of claim 1, wherein the output buffering amplifier matches the distortion component impedance to the output terminal impedance.

12. The quantum mechanical tunnel audio distortion device of claim 1, wherein the output buffering amplifier can accept feedback from the distortion component.

13. The quantum mechanical tunnel audio distortion device of claim 1, wherein the biasing circuit controls the distortion.
